(19) United States
(12) Patent Application Publication
(10) Pub. No.: US 2003/0112025 A1
(43) Pub. Date: Jun. 19, 2003

(54) Temperature control system for burn-in boards

(76) Inventors: Harold E. Hamilton, Minneapolis, MN (US); Tom A. Tremmel, New Brighton, MN (US)

Correspondence Address: Nickolas E. Westman, WESTMAN CHAMPLIN & KELLY, Suite 1600-International Centre, 900 South Second Avenue, Minneapolis, MN, 55402-3319, US

(21) Appl. No.: 10/020,348

(22) Filed: Dec. 13, 2001

(51) Int. Cl. G01R 31/02

(52) U.S. Cl. 324/760

(57) ABSTRACT

The burn-in oven is provided with a plurality of chambers, and each of the chambers has a number of stacked burn-in boards carrying devices under test. Each burn-in board is associated with an overlying fan board. The fan board divides the space between the burn-in boards so that a duct is formed on a side of the fan board opposite from its associated burn-in board. The fan boards are spaced from the burn-in boards, so that there is a space overlying the devices under tests as well. Each of the fan boards has an individual fan associated with each underlying device under test, to provide air flow through an opening directly onto the device under test. The space between each burn-in board and its associated fan board is sealed with seal plates at opposite ends of the space, and at least one of the seal plates having an adjustable damper for providing a bleed flow of cooling air through the space.

### BACKGROUND OF THE INVENTION

This invention relates to controlling the temperature of individual devices under test (DUTs) (integrated circuits) mounted on burn-in boards and held on racks in a burn-in oven. Individually controlled heaters and individually directed flows of cooling air are used to maintain the temperature of the DUT at a desired range.

The burning in of electronic circuits is commonly done, and the power requirements of the circuits tested vary substantially. It is desirable to maintain the temperature of the circuit within a close tolerance or range during the burn-in process. In addition to heaters in and for the oven, individual cartridge heaters for each of the sockets holding DUTs have also been used in the past. Cooling of regions in the ovens can be achieved when desired by adjusting the flow of air or cooling liquids, but maintaining the temperature at each individual device under test within the prescribed range is difficult because air flows can vary between the provided inlets and outlets, and hot spots can develop as well.

### SUMMARY OF THE INVENTION

The present invention, in one aspect, comprises a burn-in oven that has a plurality of racks for supporting burn-in boards for integrated circuits with a cross flow of air through horizontal ducts from one side of the oven to the other. Heat exchangers through with air flows are arranged to form the sides of compartments or sections of the oven so that the air flowing horizontally and drawn through ducts in the oven is cooled by the heat exchangers before the air flows into the next oven compartment or section. The spacing between the heat exchangers is selected so a number of DUTs are supported in the vertically spaced supports that divide the oven sections into ducts that carry airflow. The heat exchangers form passageways for flow between individual oven compartments or sections.

The flow of air is through ducts formed above each tray of DUTS. A fan carrying wall or tray overlies each tray of DUTs. The ducts are closed by side walls that extend between the duct wall and the next overlying solid tray of DUTs which forms the top of the duct. The air flow is through these ducts that are separated from the DUTs. The duct wall or tray overlying each tray of DUTS is provided with a plurality of openings. Each opening has an individually controllable fan controlling flow through that opening. Each opening and its fan is associated with and overlies a DUT socket and single DUT, so that upon energization of any fan, the DUT associated with the fan is subjected to a downward, direct flow of cooling air from the overlying duct.

The devices under test are held in sockets that also comprise heat exchangers, and preferably the sockets have vanes or fins that will radiate heat. The air from the overlying fan will flow over these fins for a cooling effect when the fan operates.

The sockets or holders for the devices under test are also provided with cartridge heaters, so that the temperature of the device under test can be raised if a signal indicating that the temperature should be raised is received from a temperature sensor on that socket.

A minor flow of air, which is passed through the heat exchangers forming the side walls of the individual oven compartments for cooling can be diverted into the space or passageways holding the DUTS, (which are separated burn-in boards), to modulate the temperature so a more even temperature for such devices is maintained. The temperature regulation is on an individual basis for each of the DUTs using a thermo couple or similar temperature sensor associated with the holder for the DUT, to either energize the cartridge heater, energize the associated fan, or leave both off. The minor flow is maintained for avoiding hot spots.

### BRIEF DESCRIPTION OF THE DRAWINGS

FIG. 1 is a side elevational view of a burn-in oven used with the present invention;

FIG. 2 is a schematic top plan view of the burn-in oven of FIG. 1;

FIG. 3 is an enlarged fragmentary view of the internal arrangement for providing a cross-flow of air in individual ducts showing fans directing flow onto the individual devices under test according to the present invention;

FIG. 4 is a fragmentary end view of a burn in oven chamber taken as on line 4-4 in FIG. 3.

FIG. 5 is a sectional view taken on line 5-5 in FIG. 4;

FIG. 6 is a schematic representation of a holder showing a device under test in position in contact with the heat exchanger;

FIG. 7 is a perspective view of the holder of the device under test shown in FIG. 6; and

FIG. 8 is a schematic block diagram of a controller and controlled functions of the present invention.

### DETAILED DESCRIPTION OF THE EXEMPLARY EMBODIMENTS

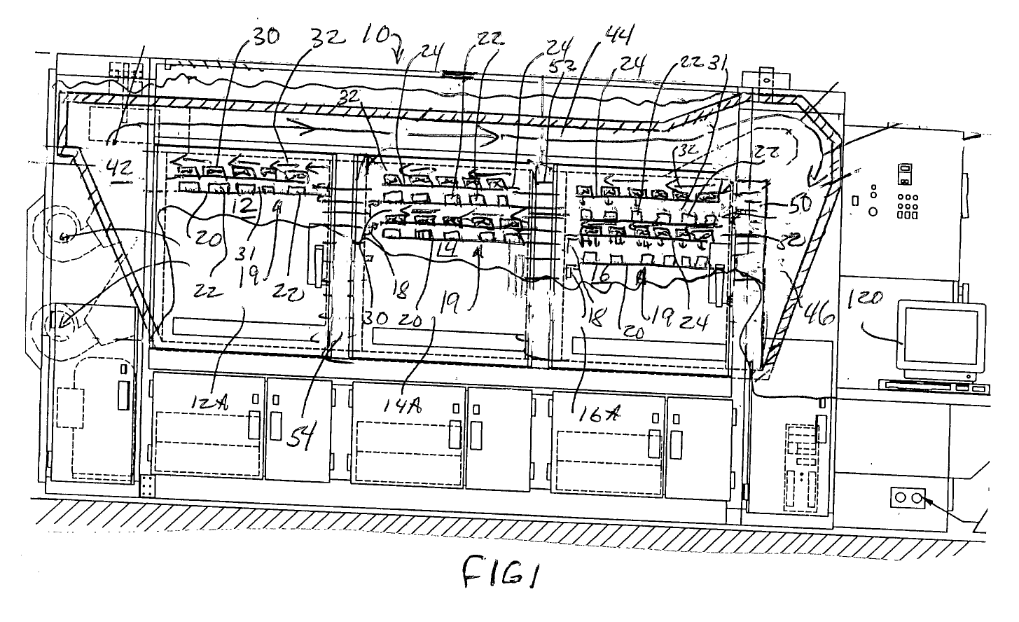

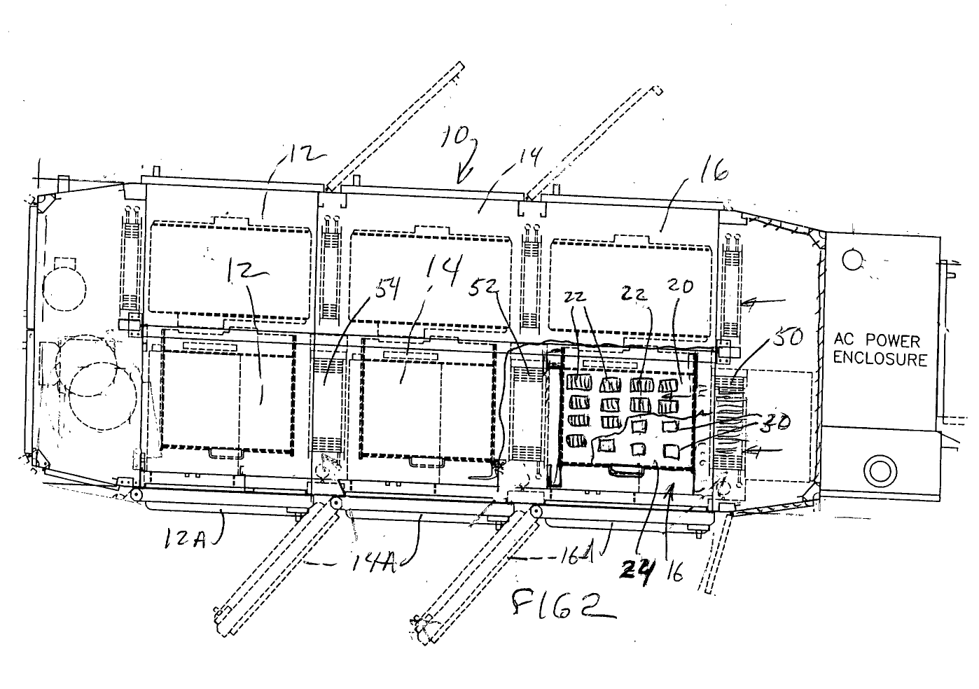

Referring to FIG. 1, a burn-in oven indicated generally at 10, has individual burn-in oven compartments, three are shown and numbered 12, 14 and 16. The burn-in oven may have one compartment, or several compartments, as needed. The oven compartments shown have access doors 12A, 14A and 16A and are provided with a number of rack or tray supports of conventional design indicated only schematically at 18 on the interior providing a rack assembly 19. Alternate rack support 18 holds a burn-in board tray 20, carrying a plurality of device under test (DUT) sockets indicated generally at 22. Each socket includes a DUT supported thereon. The oven has two sets of compartments, 12, 14, and 16.

A fan support board or tray 24 is supported above each burn-in board tray on supports 18, or with other desired supports. The fan trays 24 may remain in place in the oven, but the burn-in boards have to be removable.

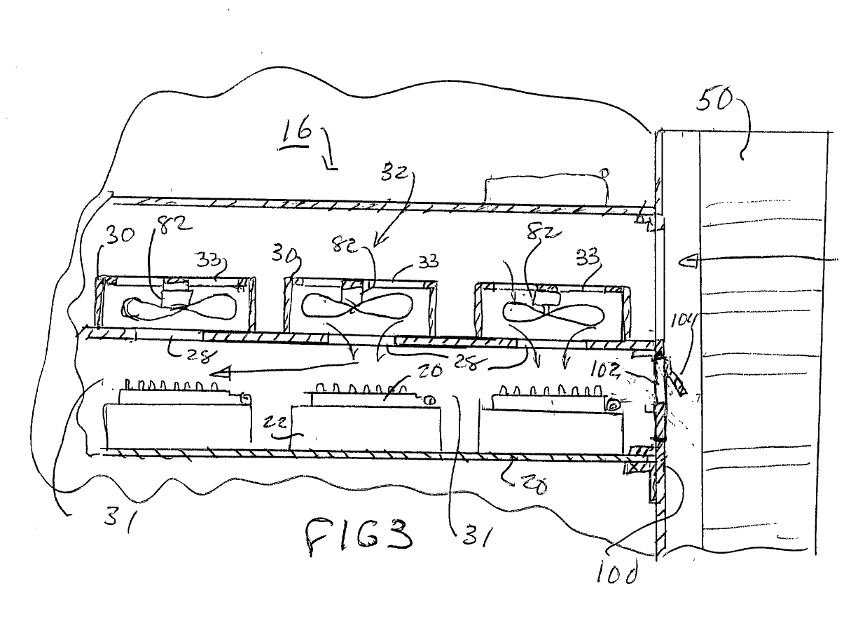

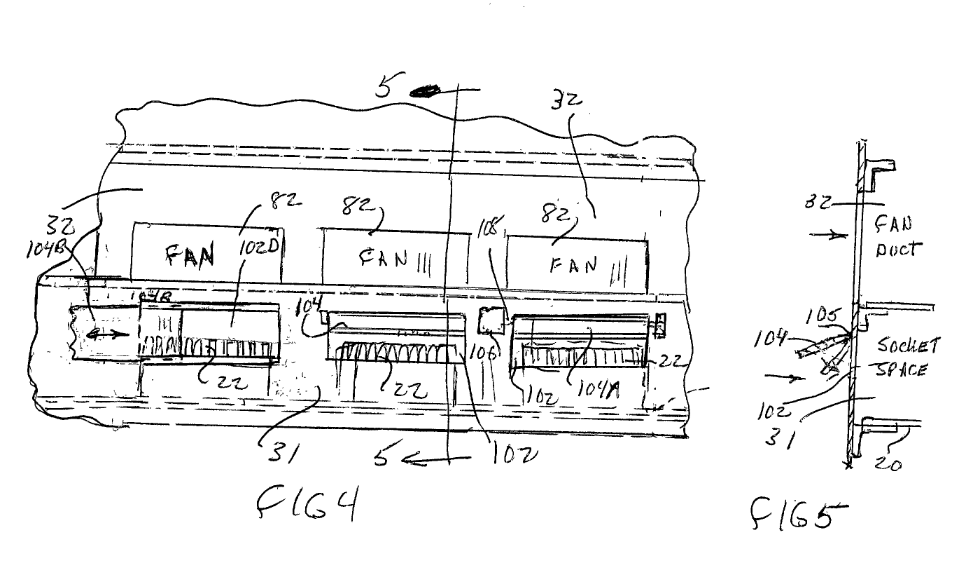

The fan boards or trays 24 each comprise a plate or wall that is imperforate or solid, except for individual fan outlet openings 28 (see FIG. 3). The individual fan openings 28 in the fan trays each lead from one of a plurality of fan boxes 30. There is one fan box 30 and fan outlet opening 28 for each individual DUT. The fan boxes are on each fan tray, and there is one fan tray above each tray of DUTs. Each fan tray 24 is spaced above the burn-in board which it is associated with as far as blowing air onto a DUT is concerned. The space above the DUTs, defined at the top by a fan tray is a cross or lateral space 31 (See FIG. 3).

The burn-in board 20 positioned above each fan tray cooperates with the underlying burn-in board to form a series of cross or lateral ducts 32 that carry a crossflow of air. The flow goes above each fan tray and the fan boxes on the tray. Each fan box 30 has an inlet opening 33 in the top, although the inlet opening can be at any desired location on the fan box. The space 31 above the burn-in boards and below each associated fan tray has a seal plate 100 at the inlet end, with control openings to provide only a small controlled flow through the seal plate, as will be explained, in addition to the flow from the controllable fans in the spaces 31. The outlet ends of the lateral spaces 31 are left open to exhaust air.

The flow of cooling air through the ducts 32 is provided by a pair of large blowers 40 shown schematically, which have outlets that open into a plenum chamber 42, and direct air through a top flow passage 44, from the fan side of the oven 10 over to the opposite side. There, walls of a plenum chamber 46 direct the flow of air into the vertically stacked ducts 32 of the oven compartment 16 and then sequentially to the compartments 14 and 12. The ducts 32 in the compartments 12, 14 and 16 are thus in a series flow arrangement across the oven. The major flow of cooling air first goes through an air to liquid heat exchanger or radiator 50, that is set up on the inlet wall of compartment 16. The heat exchanger 50 used is an air cooler with cold liquid in the heat exchange core. The heat exchanger 50 extends vertically at the inlet.

This major cooling flow goes through the cross ducts 32 in which the individual fans are placed in oven compartment 16. The flow through each duct 32 is maintained in its path and exits the ducts 32A of compartment 16 through a heat exchanger 52, between the compartments 16 and 14. The cooler air flow enters compartment 14 and passes through the ducts 32 holding the fan boxes for the DUTs in chamber or compartment 14. The airflow then exits the compartment 14 and passes through a heat exchanger 54 between the compartments 12 and 14. The air at the inlet of the ducts 32 in compartment 12 has again been cooled and flow laterally across the fan boxes 30 and then is ducted back to the blower inlets. The heater exchangers all can be of the same type.

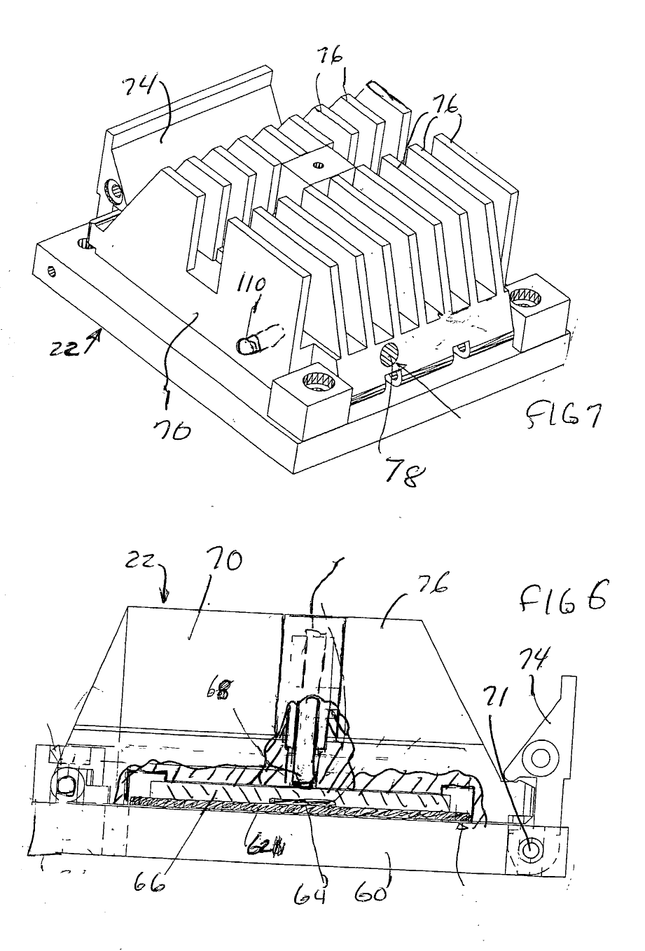

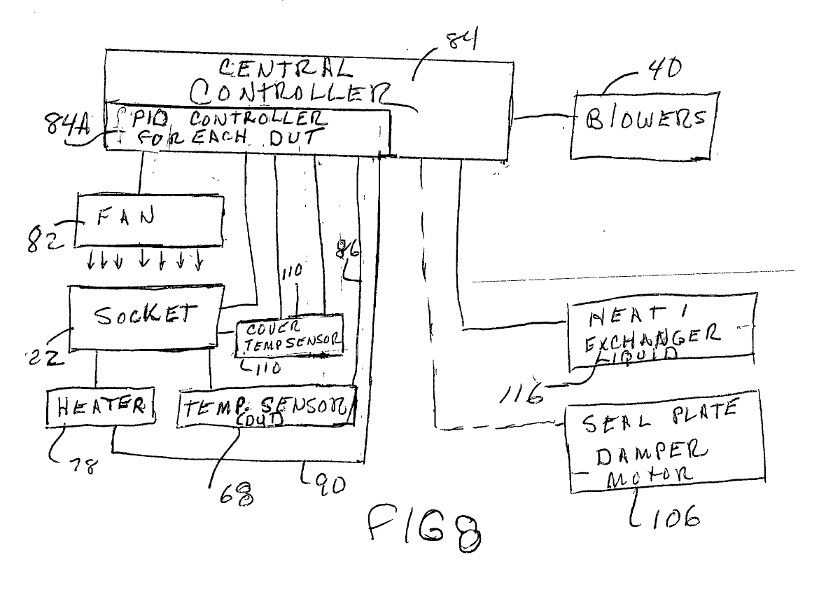

Each of the DUTs is mounted on the burn-in board inside a socket 22. As shown in FIGS. 6 and 7, the sockets 22 comprise a base 60 that includes a contact plate carrying contacts for providing control signals from a program to a circuit being tested (a DUT) and held in the respective socket. The DUT shown is a ceramic substrate 62, supporting the DUT die 64. The DUT die 64 is mounted in a case or plate 66, against which a temperature sensor 68 rests. The temperature sensor 68 is carried in a heat exchanger cover 70 that is hinged to the base of the socket at 71, and it is latched into place with a suitable latch 74. The heat exchanger cover 70, as shown in FIG. 7, has a number of fins 76 thereon to provide cooling when air flows over the fins.

In addition, a heater 78 in FIG. 7 is mounted in the cover 70 forming the heat exchanger of the socket 22. Cartridge heater 78 is shown and can be used for adding heat to the socket and thus the DUT held in that socket when desired. The heater used for heating the DUT can be other than a cartridge heater. For example a flat plate heater sandwiched in the heat sink can be used. A second temperature sensor 110 is mounted on the heat exchanger cover 70. This is used as a reference to check the thermal coupling between the DUT and the heat exchanger by comparing the temperatures sensed at sensors 68 and 110 .

The burn-in oven compartments 12, 14 and 16, each include a plurality of the DUT burn-in board trays 20, mounted on suitable supports, and as stated, the fan trays 24 are provided to overlie and run parallel to the trays 20 and thus are spaced slightly above the upper edges of the covers 70 of the sockets 22. The fan trays 24, as was stated, are imperforate except for openings 28 for each individual fan housing.

Each fan housing includes an electric fan 82, that is controlled by a separate PID controller 84A for each socket that controls the heater for that socket as well. Each PID controller 84A is part of a central controller 84 shown schematically in FIG. 8. The individual controllers 84A in the central controller 84 are programmed to control the respective fans 82 and heaters for each socket to maintain the desired temperature of the socket 22 and DUT 64 underlying the respective fan. The controller 84A for each socket receives an input signal from the corresponding temperature sensor 68 for that socket along a line 86 and in response to the temperature sensor signal, if cooling is needed, the respective controller sends out a signal to the respective fan 82 aligned with the socket 22 for the device under test that is providing the signal along the line 86.

Additionally, if heating is needed the PID controller 84A in central controller 84 will send a signal to energize the heater 78 in that particular heat exchanger for the device under test providing the temperature signal. Line 90 is used for controlling the respective heater, and turning it off and on, for the individual DUT.

It can be seen that between each of the fan trays 24 and the respective underlying burn-in board 20 the lateral space 31 forms a passageway, but flow is normally blocked by seal plates 100 at an inlet end of each space 31. The seal plates 100 block flow, except for controlled bleed or minor airflow. The seal plates 100 have dampers or adjustable gates 104 to permit a controlled amount of cross airflow through opening 102 in the seal plates 100, and this flow is combined with flow that may be provided from the fans 82 out from the exhaust or outlet end of the space or passageways 31 in which the DUTs are located. This bleed air provides a small, controllable flow across the DUTs. The seal plates block air flow into the burn-in board lateral passageway 31 for the individual DUTs except for the openings 102 for bleed flow.

The gates or dampers 104 can be used for directing a small amount of flow into the spaces 31 forming passageways, in order to modulate the temperatures of the individual devices under test with a small flow of air through this passageway, in addition to the controlled fans 82. The gates or dampers 104 can be hinged along an edge 105 and merely bent to the desired angle for controlling the size of openings 102 or can be hinged on pins and brackets.

The effective size of one or more of the openings shown at 102D in FIG. 4 can be controlled with sliding gates or dampers 104B that slide on tracks above and below the associated opening 102D, and which gate can be moved manually across the opening, as shown in FIG. 4. The position of sliding gate 104B can be set before a test is begun. The amount of bleed air is increased as the power provided to the DUT goes up. More power requires more cooling for controlling the temperature, and thus more cooling air can be provided by opening the gates or dampers to increase the effective size of the openings.

If desired, one or more of the gates can be controlled with a motor 106 (FIG. 4), driving a mounting shaft 108 supported on bearings on the seal plate 100. The motor 106 would be controlled by a portion of central controller 84. The gate 104A shown then can be adjusted in response to temperature signals, or if desired, a flow sensor can be used to regulate the feed flow.

Central controller 84 includes individual PID controllers indicated at 84A in FIG. 8, each of which controls the operation of one of the fans 82, and the corresponding heater 78 in the associated socket in response to the differential between the sensed temperature at respective socket and device under test, and the desired or set temperature point.

The temperatures can run up to about 140° C. and can be controlled quite closely with the arrangement of the present device.

If desired, the additional temperature sensor, shown schematically at 110, is used for comparing the temperature of the heat exchanger lid on the holder and the temperature of the DUT that is sensed with the temperature sensor 78. This will determine whether or not there is good thermal contact between the heat sink cover and the device under test. A low thermal resistance is desired, and intimate contact between the DUT and the heat sink is achieved using the clamp cover and the thermal resistance but can be checked with controller 84 by comparing the temperature differential between the sensor 110 and the sensor 78. Adjustments in the clamping pressure of the cover can be made or the surfaces can be cleaned for better contact.

Separate heaters for the oven are not necessary, and the heating needed is obtained from the heaters 78 on the sockets, which heat the individual DUT's. The temperature of each DUT is thus separately regulated. The central controller 84 also can have a section to control the oven cooling in response to the signal from a temperature sensor in the oven. The temperature of the heat exchanger liquid can be controlled as represented at block 116. For example, the liquid can be chilled to a different temperature if more cooling is desired. Other operations can be controlled as well. The test sequence for the DUT is not shown. It is controlled independently as part of a software program in a control computer 120 shown in FIG. 1. Central controller 84 can be part of the control computer 120, as well, but each PID controller 84A can be separately programmed for the respective socket and DUT.

Although the present invention has been described with reference to preferred embodiments, workers skilled in the art will recognize that changes may be made in form and detail without departing from the spirit and scope of the invention.

What is claimed is:

1. A burn-in oven having a heat control system comprising an oven chamber, at least one burn-in board supporting a plurality of devices under test, a fan board spaced from the burn-in board and overlying the devices under test, a separate fan outlet opening through the fan board overlying each device under test, a separate controllable fan for providing a flow of air through each opening onto a device under test, a sealing plate at one end of a space between the burn-in board carrying the device under test and the overlying fan board, and at least one end of the space having an adjustable damper movable to adjust the size of the opening to the space at the at least one end, and a source of cooling air at one end of the oven chamber, and an exhaust for the cooling air at an opposite end whereby a flow of air is passed across the upper surface of the fan board, and selectively through the space when the damper is opened.

2. The burn-in oven of claim 1, including a controller for controlling the opening of the damper in response to a selected parameter.

3. The burn-in oven of claim 1, wherein each device under test comprises a socket, holding a devise under test, a heater on the socket to heat the device under test, a temperature sensor associated with each socket to provide a temperature signal indicating the temperature of the device under test, and a controller for controlling the fan at the fan outlet and the heater for each such device under test.

4. The burn-in oven of claim 1, wherein said separate fans each have a fan housing, a separate electric motor driving each fan in each housing, and the housings having an inlet opening for permitting air to be driven by the fan through the fan outlet onto an aligned device under test.

5. The burn-in oven of claim 1, wherein each device under test comprises a socket, an integrated circuit in the socket, and said socket having heat radiating fins thereon facing toward the fan opening.

6. The burn-in oven of claim 1, wherein said source of cooling air comprises a plenum chamber at the one end of said oven chamber, a fan providing an airflow to the plenum chamber, and the fan receiving a return airflow from the oven chamber.

7. The burn-in oven of claim 1, wherein there are a plurality of oven chambers, and each of the chambers has at least one burn-in board supporting a plurality of devices under test, and a separate fan board spaced from each burn-in board.

8. The burn-in oven of claim 5, wherein each socket has a heater therein, a separate controller for controlling the fan and heater for each socket individually, each said fan and heater being controllable by its associated controller to maintain the temperature sensed by the temperature sensor at a desired range.

9. The burn-in oven of claim 1, wherein the one end of said oven chamber has a heat exchanger for cooling air passing therethrough, said cooling air passing through the heat exchanger before entering the space.

10. The burn-in oven of claim 1, wherein there are a series of vertically stacked burn-in boards in the oven chamber, each with an associated fan board spaced from the burn-in board on a side of the burn-in boards toward the devices under test, and wherein each burn-in board forms a duct in combination with an underlying fan board that is associated with a burn-in board on an opposite side of the fan board from the duct, the cooling air cooling the surface of the burn-in board facing the underlying the fan board.

11. The burn-in oven of claim 10, wherein there are a series of oven chambers side-by-side, and a heat exchanger between each of the adjacent oven chambers, the airflow from one oven chamber passing to one other oven chamber and through the heat exchanger between the one chamber and the other chamber.

12. In combination, a burn-in oven, and a plurality of first and second trays in the oven, combined with a cooling air flow source, the burn-in oven defining a compartment, a plurality of first trays forming burn-in boards having devices under test mounted thereon in a preselected array; a plurality of second trays comprising fan trays spaced from each of the burn-in board trays on a side of each burn-in board tray so that the fan trays overlie the devices under test and form a laterally extending space between such trays, an airflow duct formed on a side of each fan tray by an overlying burn-in board tray, the ducts extending laterally across a surface of each fan tray, a plurality of controllable fans mounted on each fan tray and having a fan opening substantially directly overlying each underlying device under test on an associated burn-in board tray, the space between each burn-in board tray and its associated overlying fan tray being adjustably operable, a source of fluid flow on one lateral side of the ducts formed by the fan tray and an overlying burn-in board tray, a controlled size opening from the source of fluid to the space and a controller for selectively controlling the operation of each fan as a function of a temperature signal provided from each of the devices under test.

13. The combination of claim 12 and at least one adjustable damper for adjustably opening each respective space between the burn-in trays and its overlying fan tray, the controller adjusting the position of the damper to provide a substantially constant bleed air flow through the associated space.

14. The combination of claim 13, wherein said devices under test comprise sockets supporting an integrated circuit under test, a finned heat exchanger on the socket, said finned heat exchanger extending into the space between each burn-in board tray and its associated overlying fan tray.

15. The combination of claim 13, including a heat exchanger for cooling air flow entering the ducts on one end of the burn-in oven.

16. The combination of claim 12, wherein said burn-in oven has a blower for providing the flow of cooling air to an inlet end of said ducts formed with said burn-in board trays and the fan trays, and a flow passageway carrying air from said blower to the inlet end to provide cooling air to each of the ducts.

17. The combination of claim 14 and individual heaters for heating each of the devices under test, said controller receiving a temperature signal from the respective device under test, and controlling its associated fan and heater to maintain the temperature sensed at a desired range.
